(19) United States
(12) Patent Application Publication
(10) Pub. No.: US 2019/0355871 A1
(43) Pub. Date: Nov. 21, 2019

(54) HIGH-EFFICIENCY 1,000NM INFRARED LIGHT EMITTING DIODE, AND MANUFACTURING METHOD THEREOF

(71) Applicant: AUK CORP., Iksan-si (KR)

(72) Inventor: Hyung Joo LEE, Gwangju (KR)

(73) Assignee: AUK CORP., Iksan-si (KR)

(21) Appl. No.: 16/411,101

(22) Filed: May 13, 2019

(30) Foreign Application Priority Data
May 21, 2018 (KR) 10-2018-0057922

(51) Int. Cl. H01L 33/12; H01L 33/06; H01L 33/00; H01L 33/14; H01L 33/36; H01L 33/30

(52) U.S. Cl. CPC H01L 33/12; H01L 33/06; H01L 33/0025; H01L 33/30; H01L 33/36; H01L 33/0062; H01L 33/14

(57) ABSTRACT

The present invention relates to an infrared light emitting diode and a manufacturing method thereof, and more specifically, to a 1,000 nm infrared light emitting diode with improved light emitting efficiency through compensation of strain, and a manufacturing method thereof.

### BACKGROUND OF THE INVENTION

### Priority Claim

This application claims the benefit of prior Korean Application No. KR 10-2018-0057922 filed on May 21, 2018, each of which is incorporated by reference in its entirety.

### FIELD OF THE INVENTION

The present invention relates to an infrared light emitting diode and a manufacturing method thereof, and more specifically, to a 1,000 nm infrared light emitting diode with improved light emitting efficiency through compensation of strain, and a manufacturing method thereof.

### BACKGROUND OF THE RELATED ART

Infrared light emitting diodes are manufactured using MOCVD system, which is capable of performing high-quality growth. An infrared light emitting diode which emits a wavelength of 900 nm or longer uses a GaAs substrate 8 having a high lattice matching rate and an effect of high cost reduction (economical efficiency) as shown in FIG. 1. An n-type Al_{z}Ga_{1-z}As lower confinement layer 7 (0.1<z<0.7), an active layer 4, and a p-type Al_{z}Ga_{1-z}As upper confinement layer 3 (0.1<z<0.7) having almost the same lattice constant are grown on the GaAs substrate 8. In addition, a p-type window layer 2 for current spreading effect is grown on the top of the upper confinement layer 3 as much as 3 um or more to increase effectively optical efficiency. An upper electrode 1 is formed on the top of the p-type window layer 2, and a lower electrode 9 is formed on the bottom of the GaAs substrate E. The active layer 4 stacked between the n-type confinement layer 7 and the p-type confinement layer 3 is configured of alternately and repeatedly stacked quantum barrier layers 5 and quantum well layers 6, and the wavelength of emitted infrared light is adjusted by the constituent materials and compositional changes of the quantum well layer 6. For example, in the case of an infrared light emitting diode having a center wavelength of 940 nm (a wavelength in which a peak wavelength is positioned at 940±10 nm), an In_{0.07}Ga_{0.93}As quantum well layer and a GaAs quantum barrier layer are repeatedly stacked.

In the case of the infrared light emitting diode like this (>940 nm wavelength), since the lattice constants of the materials configuring the quantum well layer used to emit light of a specific wavelength are different from that of the substrate, tensile or compressive strain is generated in the stacking process, and the strain accumulated in the repeated stacking process leads to degradation of light emitting efficiency of the light emitting diode.

Korean Patent Application No. 10-2017-0059347 applied by the inventor of the present invention discloses a method of inserting a GaInP tensile strain compensation layer under the active layer configured of an In_{0.07}Ga_{0.93}As quantum well and a GaAs quantum barrier in a light emitting diode having a 940 nm center wavelength to improve the compressive strain of the quantum well.

In addition, Korean Patent Application No. 10-2018-0017518 applied by the inventor of the present invention discloses a method of using a GaAsP quantum barrier, instead of the GaAs quantum barrier, together with the In_{0.07}Ga_{0.93}As quantum well to improve the compressive strain of the quantum well.

In addition, Korean Patent Application No. 10-2018-0017518 applied by the inventor of the present invention discloses a method of using an AlGaAs buffer layer together to compensate for a high difference of unbalanced strain which is generated when the In_{0.07}Ga_{0.93}As quantum well and the GaAsP quantum barrier are used to improve the compressive strain of the quantum well.

However, although these methods are effective in an infrared light emitting diode of a 940 nm center wavelength using an In_{0.07}Ga_{0.93}As quantum well, it is not effective in an infrared light emitting diode of a 1,000 nm center wavelength. This is since that in the case of a light emitting diode having a center wavelength of 1,000 nm, the ratio of In in the quantum well is higher than that of a light emitting diode having a center wavelength of 940 nm and thus has a high compressive strain rate (e.g., a compressive strain rate of 10,000 ppm or higher, for example, In_{0.15}Ga_{0.85}As compressive strain: approximately +11,000 ppm) compared with the substrate.

Accordingly, a new method for improving the high compressive strain characteristic of the InGaAs quantum well layer used in a 1,000 nm light emitting diode is continuously required.

### SUMMARY OF THE INVENTION

Therefore, the present invention has been made in view of the above problems, and it is an object of the present invention to provide a method for preventing degradation of efficiency generated due to lattice mismatch between the quantum well layer and the substrate in an infrared light emitting diode having a center wavelength of 1,000 nm.

Another object of the present invention is to provide a light emitting diode, efficiency of which is improved by eliminating lattice mismatch of the quantum well layer and the substrate in an infrared light emitting diode having a 1,000 nm center wavelength.

To accomplish the above objects, according to one aspect of the present invention, there is provided an infrared light emitting diode including: an InₓGa₁₋ₓAs quantum well layer (0.13≤x≤0.17); a GaAs_{1-y}P_{y} quantum barrier layer (0.07≤y≤0.11); and an active layer including a GaInP strain compensation barrier having compressive strain lower than that of the quantum barrier layer, and a GaAs buffer layer.

In the present invention, the term ‘1,000 nm center wavelength’ means that the peak wavelength is within a range of 1,000±20 nm, more accurately 1,000±10 nm.

In the present invention, it is understood that the term ‘InGaAs’ means a layer practically configured of In, Ga and As.

In the present invention, the term ‘InGaAs quantum well layer’ means an InₓGa₁₋ₓAs quantum well layer (0.13≤x≤0.17).

In the present invention, it is understood that the term ‘GaAsP’ means a layer practically configured of Ga, As and P.

In the present invention, the term ‘GaAsP quantum barrier layer’ means a GaAs_{1-y}P_{y} quantum barrier layer (0.07≤y≤0.11).

In the present invention, it is understood that the term ‘GaInP’ means a layer practically configured of In, Ga and P.

In the present invention, the term ‘compressive strain’ means having an arcsec value smaller than the arcsec value of the GaAs substrate.

In the present invention, the term ‘tensile strain’ means having an arcsec value larger than the arcsec value of the GaAs substrate.

In the present invention, the infrared light emitting diode may be a light emitting diode having a 1,000 nm center wavelength.

Although it is not theoretically limited, since the difference of lattice constant between the InGaAs quantum well layer for 1,000 nm center wavelength and the GaAs substrate is large (e.g., In_{0.15}Ga_{0.85}As/GaAs:Δa/a≥+11,000 ppm [compressive strain]; a rate of change with respect to the lattice constant), whereas lattice constants of the p-type confinement layer, the n-type confinement layer and the window layer are almost the same as that of the GaAs substrate (e.g., Al_{0.3}Ga_{0.7}As/GaAs:Δa/a≤+400 ppm [compressive strain]; a rate of change with respect to the lattice constant), efficiency of the active layer of the light emitting diode is improved by using a GaAsP quantum barrier layer having tensile strain to compensate for compressive strain of the InGaAs quantum well layer and introducing a GaInP strain compensation barrier having low tensile strain compared with the GaAsP quantum barrier layer between the InGaAs quantum well layer and the GaAsP quantum barrier layer to enhance light emitting efficiency by improving the defect generated due to introduction of the GaAsP quantum barrier layer having an opposite polarity, and the light emitting efficiency is improved by stacking a GaAs buffer layer between the GaInP strain compensation barrier and the InGaAs quantum well layer and/or between the GaInP strain compensation barrier and the GaAsP quantum barrier layer so that the InGaAs quantum well layer and the GaAsP quantum barrier layer may not be affected by the GaInP strain compensation barrier in the process of growing the GaInP strain compensation barrier when the GaInP strain compensation barrier is introduced.

In the present invention, the InGaAs quantum well layer and the GaAsP quantum barrier layer are alternately stacked, and the GaInP strain compensation barrier is preferably positioned between the InGaAs quantum well layer and the GaAsP quantum barrier layer to mitigate abrupt change of strain between the alternately stacked InGaAs quantum well layer and GaAsP quantum barrier layer.

In the present invention, the GaAs buffer layer is preferably stacked between the InGaAs quantum well layer and the GaInP strain compensation barrier and/or between the GaAsP quantum barrier layer and the GaInP strain compensation barrier.

In the present invention, the infrared light emitting diode having a 1,000 nm center wavelength may be a diode in which the InGaAs quantum well layer and the GaAsP quantum barrier layer are alternately stacked two or more times, preferably five or more times, and a GaAs buffer layer, a GaInP strain compensation barrier and a GaAs buffer layer are grown and stacked in order in the MOCVD method between the alternately stacked InGaAs quantum well layer and GaAsP quantum barrier layer.

In an embodiment of the present invention, the infrared light emitting diode having a 1,000 nm center wavelength includes: a GaAs substrate; a first type AlGaAs lower confinement layer grown on the substrate; an active layer grown on the first type AlGaAs lower confinement layer; a second type AlGaAs upper confinement layer grown on the active layer; a p-type window layer; and an upper electrode and a lower electrode contacting with a top surface and a bottom surface of the p-type window layer and the GaAs substrate. Here, the active layer may be an active layer in which the InGaAs quantum well layer and the GaAsP quantum barrier layer are alternately stacked five or more times, and a GaAs buffer layer, a GaInP strain compensation barrier and a GaAs buffer layer are grown and stacked in order in the MOCVD method between the alternately stacked InGaAs quantum well layer and GaAsP quantum barrier layer.

In the present invention, the GaAs substrate is a substrate on which a lower confinement layer is grown, and a lower electrode may be formed on the bottom surface of the substrate. In an embodiment of the present invention, the GaAs substrate may be a type the same as that of the first type AlGaAs lower confinement layer, preferably an n-type GaAs substrate. For example, the n-type GaAs substrate may have an arcsec value of 32.9.

In the present invention, it is preferable to use an AlGaAs lower confinement layer of a type the same as that of the GaAs substrate, and the AlGaAs lower confinement layer preferably has an arcsec value of a level practically the same as that of the n-type substrate, i.e., a value ±0.5 of the arcsec value of the n-type substrate. In a preferred embodiment, the ratio of Al to Ga may be adjusted so that the AlGaAs may have an arcsec value of a level practically the same as that of the n-type substrate. For example, AlGaAs may be expressed as Al_{z}Ga_{1-z}As, and z may be 0.3.

In the present invention, the InGaAs quantum well layer may use InₓGa₁₋ₓAs in a range of 0.13≤x≤0.17, further preferably 0.14≤x≤0.16, to emit a center wavelength of 1,000 nm, and further preferably, the InGaAs quantum well layer may be In_{0.15}Ga_{0.85}As and may be slightly adjusted according to thickness.

In the present invention, the GaAsP quantum barrier layer has tensile strain to compensate for the compressive strain of the InGaAs quantum well layer, may preferably use GaAs_{1-y}P_{y} in a range of 0.075≤y≤0.11, further preferably 0.08≤y≤0.10, to have an effect of compensating for strain and improving optical efficiency to a certain extent, and further preferably, the GaAsP quantum barrier layer may be GaAs_{0.91}P_{0.09} and may be slightly adjusted according to thickness.

In the present invention, the GaInP strain compensation barrier may be a compensation barrier having tensile strain lower than that of the GaAsP quantum barrier layer to have an improved light emitting efficiency by eliminating the defects caused by opposite polarities between the InGaAs quantum well layer and the GaAsP quantum barrier layer, and may be preferably Ga_{z}In_{1-z}P, where 0.50≤z≤0.59, further preferably 0.51≤z≤0.55, and most preferably Ga_{0.53}In₀₄₇P.

In the present invention, the GaAs layer is used to eliminated interactions of the quantum well layer, the quantum barrier layer and the strain compensation barrier, and accordingly, the GaAs layer is preferably grown thereon whenever a quantum well layer, a quantum barrier layer or a strain compensation barrier is grown so that the quantum well layer, the quantum barrier layer and the strain compensation barrier may not directly contact with each other. The GaAs layer is preferably an un-doped GaAs layer.

In an embodiment of the present invention, in the active layer, the InGaAs quantum well layer and the GaAsP quantum barrier layer may be alternately and repeatedly stacked two or more times, preferably three or more times, further preferably four or more times, and most preferably five or more times.

In the present invention, the AlGaAs upper confinement layer may be a p-type AlGaAs lower confinement layer and preferably has a composition the same as that of the n-type AlGaAs lower confinement layer.

In an embodiment of the present invention, in the active layer, the quantum well layer and the quantum barrier layer may have a thickness of 5 nm and 10 nm and may have practically the same thickness. In addition, in the active layer, the AlGaAs strain compensation barrier and the GaAs buffer layer preferably have a thickness of 5 nm and 2 nm, respectively.

According to an aspect of the present invention, there is provided a light emitting diode including a substrate, a lower confinement layer, an active layer having a quantum barrier layer and a quantum well layer, an upper confinement layer and a window layer, in which the quantum well layer has compressive strain, and the quantum barrier layer has tensile strain. A strain compensation barrier having tensile strain lower than the tensile strain of the quantum well layer is provided between the quantum well layer and the quantum barrier layer, and a GaAs buffer layer is provided on the top and bottom surfaces of the strain correction layer.

According to an aspect of the present invention, there is provided a method of manufacturing a light emitting diode including a substrate, a lower confinement layer, an active layer having a quantum barrier layer and a quantum well layer, an upper confinement layer, and a window layer, and the method includes the steps of repeatedly forming a quantum well layer having compressive strain and a quantum barrier layer having tensile strain, forming a strain compensation barrier having tensile strain lower than the tensile strain of the quantum barrier layer between the quantum well layer and the quantum barrier layer, and forming a GaAs layer on the top and bottom surfaces of the strain correction layer.

In the present invention, tensile strain of the strain compensation barrier may be 1 to 50%, preferably 2 to 40%, further preferably 3 to 30%, and most preferably 5 to 20% of the tensile strain of the quantum barrier layer.

### BRIEF DESCRIPTION OF THE DRAWINGS

FIG. 1 is a view schematically showing the structure of a 940 nm infrared light emitting diode having an active layer in which an InₓGa₁₋ₓAs quantum well layer and a GaAs quantum barrier layer manufactured by a MOCVD system in a conventional technique are alternately stacked.

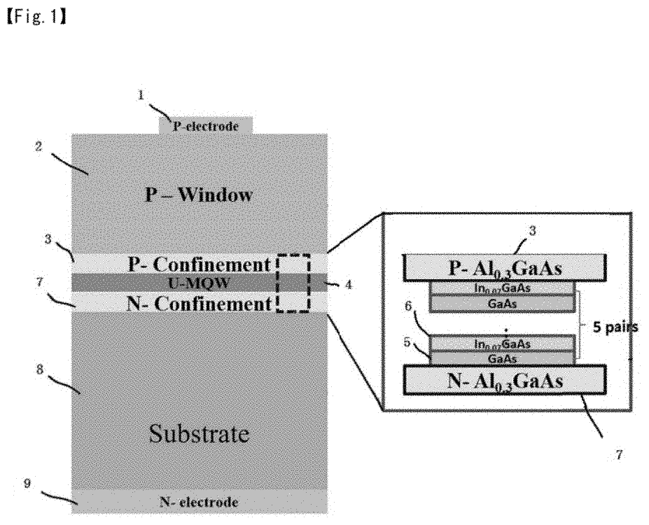

FIG. 2 is a view schematically showing the structure of a 1,000 nm infrared light emitting diode having an active layer configured of an InₓGa₁₋ₓAs quantum well layer and a GaAsP quantum barrier layer alternately stacked and manufactured by a MOCVD system, and a GaAs buffer layer, an InₓGa₁₋ₓP strain compensation barrier and a GaAs buffer layer stacked there between according to the present invention.

FIG. 3 is a view showing the structure of various active layers that can be used in the light emitting diode of FIG. 2. (a) InGaAs/GaAs, (b) InGaAs/GaAsP, (c) InGaAs/GaAs/GaInP/GaAs/GaAsP

FIG. 4 is a view showing the XRD characteristics according to composition of (a) an In_{0.15}Ga_{0.85}As layer configuring a quantum well layer and (b) a GaAs_{1-y}P_{y} layer configuring a quantum barrier layer.

FIG. 5 is a view showing the PL characteristic according to composition of GaAsP of an InGaAs/GaAs active layer and an InGaAs/GaAs_{1-y}P_{y} active layer of the prior art.

FIG. 6 is a view showing the PL characteristic according to composition of GaInP in an InGaAs/GaAs/Ga_{z}In_{1-z}P/GaAs/GaAsP active layer.

FIG. 7 is a view showing the optical characteristics of 1,000 nm infrared light emitting diodes having a conventional InGaAs/GaAs active layer, a compared InGaAs/GaAsP active layer, and an InGaAs/GaAs/Ga_{z}In_{1-z}P/GaAs/GaAsP active layer according to the present invention.

### DESCRIPTION OF SYMBOLS

10: Light emitting diode
11: Upper electrode
12: Window layer
13: P-type confinement layer
17: n-type confinement layer
18: Substrate
19: Lower electrode
20: Active layer
21: Quantum well
22: Quantum barrier
23: Strain correction layer
24: Buffer layer

### DETAILED DESCRIPTION OF THE PREFERRED EMBODIMENT

Hereinafter, the present invention will be described in detail through the embodiments.

### Embodiment 1

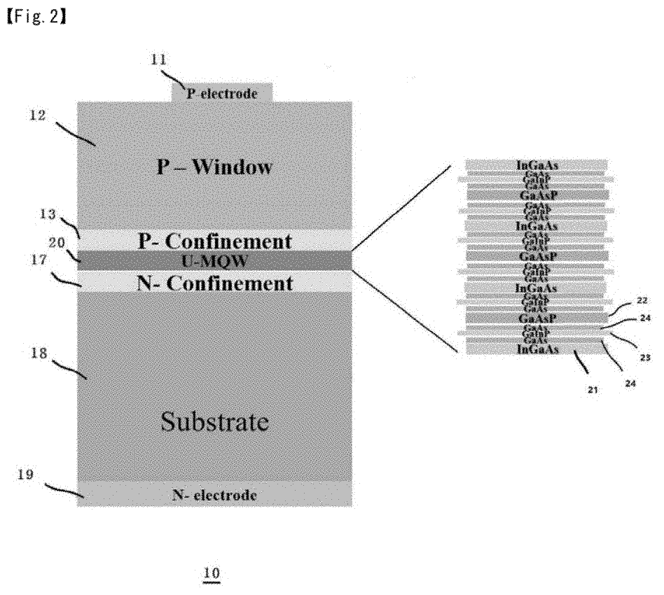

FIG. 2 is a view schematically showing the structure of a 1,000 nm infrared light emitting diode having an active layer configured of an InGaAs quantum well layer and a GaAsP quantum barrier layer alternately stacked by a MOCVD system, and a GaAs buffer layer, an InGaP strain compensation barrier and a GaAs buffer layer stacked between the alternately stacked quantum well layer and quantum barrier layer.

As shown in FIG. 2, a 1,000 nm infrared light emitting diode 10 has a lower n-type GaAs substrate 18, an n-type lower confinement layer 17 configured of Al_{0.3}Ga_{0.7}As grown on the n-type GaAs substrate 18, an active layer 20 grown on the n-type lower confinement layer 17, a p-type upper confinement layer 13 grown on the active layer 20 as Al_{0.3}Ga_{0.7}As, and a window layer 12 configured of Al_{0.2}Ga_{0.8}As grown on the p-type upper confinement layer 13 at a thickness of 5 μm to obtain a current diffusion effect and an emission cone zone expansion effect of the infrared light emitting diode. A lower electrode 19 configured of AuGeNi is formed on the bottom of the n-type GaAs substrate 18, and an upper electrode 11 configured of AuZn is formed on the top of the window layer 12.

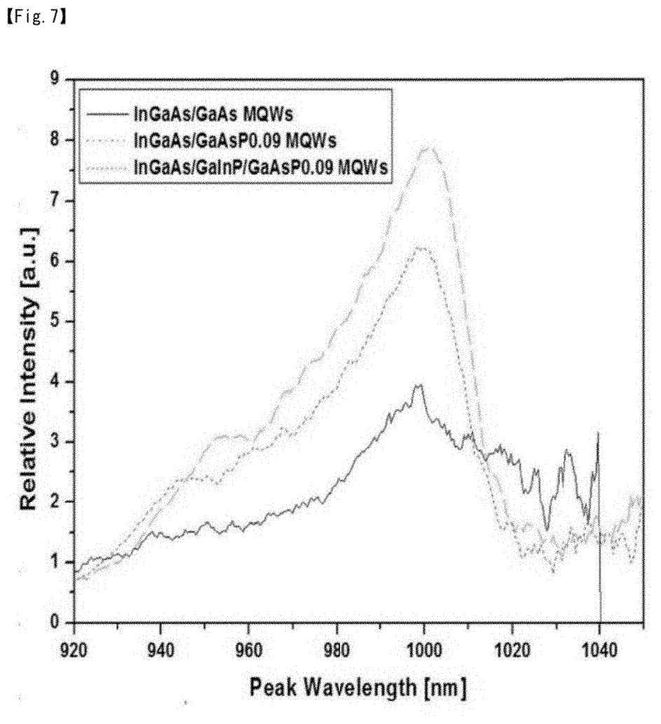

In the active layer 20, an In_{0.15}Ga_{0.85}As quantum well 21 and a GaAs_{0.91}P_{0.09} quantum barrier 22 are alternately and repeatedly grown five times, and a GaAs buffer layer 24, a Ga_{0.53}In_{0.47}P strain compensation barrier 23, and a GaAs buffer layer 24 are grown between the quantum well 21 and the quantum barrier 22. The Ga_{0.53}In_{0.47}P strain compensation barrier 23 has tensile strain of 1,000 ppm. Photoluminescence (PL) intensity of a 1,000 nm center wavelength diode 10 having the layer structure of FIG. 2 is measured. A result of the measurement is shown in FIG. 7. (InGaAs/GaInP/GaAsP0.09MQWs)

### Comparative Embodiment 1

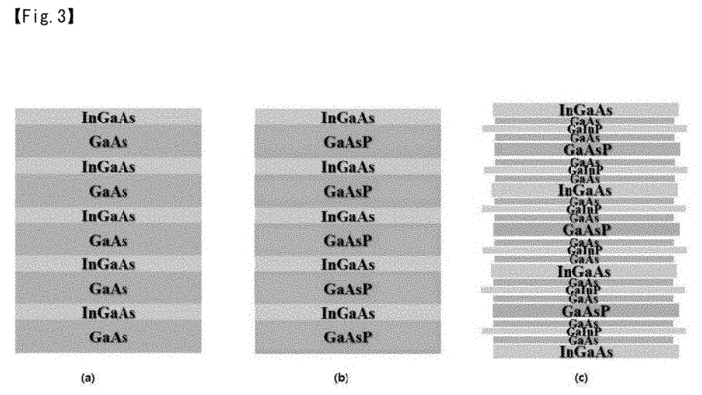

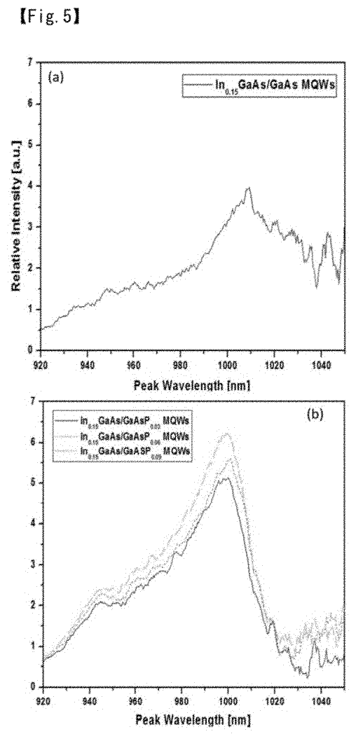

A light emitting diode having a structure the same as that of the diode 10 of embodiment 1, except that the In_{0.15}Ga_{0.85}As quantum well layer and the GaAs quantum barrier layer are alternately stacked five times as shown in FIG. 3(a), is manufactured, and photoluminescence (PL) intensity is measured. A result of the measurement is shown in FIG. 5(a).

### Comparative Embodiment 2-1

A light emitting diode having a structure the same as that of the diode 10 of embodiment 1, except that the In_{0.15}Ga_{0.85}As quantum well layer and the GaAs_{0.97}P_{0.03} quantum barrier layer are alternately stacked five times as shown in FIG. 3(b), is manufactured, and photoluminescence (PL) intensity is measured. A result of the measurement is shown in FIG. 5(b).

### Comparative Embodiment 2-1

A light emitting diode having a structure the same as that of the diode 10 of embodiment 1, except that the In_{0.15}Ga_{0.85}As quantum well layer and the GaAs_{0.94}P_{0.06} quantum barrier layer are alternately stacked five times as shown in FIG. 3(b), is manufactured, and photoluminescence (PL) intensity is measured. A result of the measurement is shown in FIG. 5(b).

### Comparative Embodiment 2-3

A light emitting diode having a structure the same as that of the diode 10 of embodiment 1, except that the In_{0.15}Ga_{0.85}As quantum well layer and the GaAs_{0.91}P_{0.09} quantum barrier layer are alternately stacked five times as shown in FIG. 3(b), is manufactured, and photoluminescence (PL) intensity is measured. A result of the measurement is shown in FIG. 5(b).

### Embodiment 2

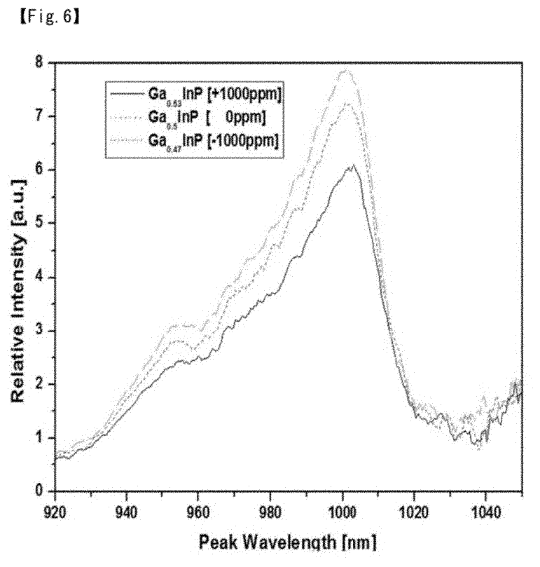

In embodiment 1, the active layer 20 has an In_{0.15}Ga_{0.85}As quantum well 21 and a GaAs_{0.91}P_{0.09} quantum barrier 22 alternately and repeatedly grown five times, and a GaAs buffer layer 24, a Ga_{0.50}In_{0.50}P strain compensation barrier 23, and a GaAs buffer layer 24 are grown between the quantum well 21 and the quantum barrier 22. Here, the Ga_{0.50}In_{0.50}P strain compensation barrier does not have tensile strain. Photoluminescence (PL) intensity of a 1,000 nm center wavelength diode 10 having the layer structure of FIG. 2 is measured. A result of the measurement is shown in FIG. 6.

### Comparative Embodiment 3

In embodiment 1, the active layer 20 has an In_{0.15}Ga_{0.85}As quantum well 21 and a GaAs_{0.91}P_{0.09} quantum barrier 22 alternately and repeatedly grown five times, and a GaAs buffer layer 24, a Ga_{0.47}In_{0.53}P strain compensation barrier 23, and a GaAs buffer layer 24 are grown between the quantum well 21 and the quantum barrier 22. Here, the Ga_{0.47}In_{0.53}P strain compensation barrier has tensile strain of −1,000 ppm. Photoluminescence (PL) intensity of a 1,000 nm center wavelength diode 10 having the layer structure of FIG. 2 is measured. A result of the measurement is shown in FIG. 6.

Discussions

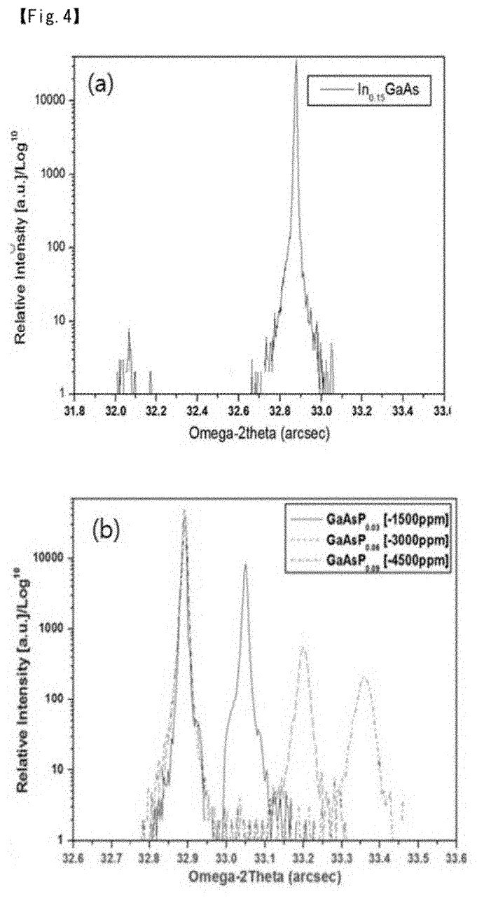

FIG. 4 is a view showing the XRD characteristics of (a) an In_{0.15}Ga_{0.85}As quantum well layer and (b) a GaAs_{1-y}P_{y} strain compensation barrier. All the layers are grown on the GaAs substrate as a single layer and scanned under the condition of omega-2theta. The layers have characteristics of compressive strain when they move in a direction of arcsec lower than that of the GaAs substrate (32.9 arcsec) and have characteristics of tensile strain when they move in a direction of arcsec higher than that of the GaAs substrate.

As shown in FIG. 4, in the case of In_{0.15}Ga_{0.85}As used as a light emission quantum well of a 1,000 nm infrared light emitting diode, it has extremely high compressive strain (+11,000 ppm) at 32.05 arcsec compared with that of GaAs (32.9 arcsec), and GaAs_{1-y}P_{y} has tensile strain. GaAs_{1-y}P_{y} shows a tendency of increasing the degree of tensile strain as the y value increases, and it is known that it has tensile strain of GaAs_{0.97}P_{0.03} (−1,500 ppm), GaAs_{0.94}P_{0.05} (−3,000 ppm), and GaAs_{0.91}P_{0.09} (−4,500 ppm).

As shown in comparative embodiment 1, when a quantum well layer having high compressive strain is alternately stacked together with a GaAs quantum barrier layer without having compressive strain, the 1,000 nm center wavelength light emitting diode does not improve the compressive strain caused by the quantum well layer and has a low PL intensity of 4 units as shown in FIG. 5(a).

As shown in comparative embodiments 2-1, 2-2 and 2-3, when a quantum well layer having high compressive strain is alternately stacked together with a GaAs_{1-y}P_{y} quantum barrier layer having tensile strain, the 1,000 nm center wavelength light emitting diode improves the compressive strain caused by the quantum well layer by the quantum barrier layer having tensile strain and has an improved PL intensity of 5 to 6 units as shown in FIG. 5(b). A quantum barrier layer having high tensile strain shows a relatively high PL intensity compared with a quantum barrier layer having low tensile strain.

As shown in embodiment 1, embodiment 2 and comparative embodiment 3, when a strain compensation barrier of Ga_{z}In_{1-z}P and a buffer layer of GaAs are positioned between the quantum well layer and the quantum barrier layer in the form of a composite layer of GaAs/Ga_{z}In_{1-z}P/GaAs while the In_{0.15}Ga_{0.85}As quantum well layer and the GaAs_{0.91}P_{0.09} a quantum barrier layer are alternately stacked, the photoluminescence (PL) characteristic is affected by the characteristic of the strain compensation barrier of Ga_{z}In_{1-z}P.

As shown in comparative embodiment 3, when the Ga_{z}In_{1-z}P strain compensation barrier has compressive strain (z=0.53) in the form of Ga_{0.53}In_{0.47}P, the PL intensity is 6.2 units, which is slightly lower than or almost the same as that of a case where GaAs of the GaAs/Ga_{z}In_{1-z}P/GaAs layer does not exist between the quantum well layer and the quantum barrier layer (comparative embodiment 2-3).

Contrarily, as shown in embodiment 1, when the Ga_{z}In_{1-z}P strain compensation barrier has tensile strain (z=0.53) in the form of Ga_{0.47}In_{0.53}P, the PL intensity greatly increases to 7.9 units.

In addition, as shown in embodiment 2, even when the Ga_{z}In_{1-z}P strain compensation barrier has zero strain (x=0.5) in the form of Ga_{0.50}In_{0.50}P, the PL intensity greatly increases to 7.2 units. Such a result shows that the tensile strain characteristic of the Ga_{z}In_{1-z}P strain compensation barrier has adjusted strain non-uniform condition (compensation strain condition: +6, 500 ppm) generated by the In_{0.15}Ga_{0.85}As/GaAs_{0.91}P_{0.09} MQW in a more balanced way, and contrarily, it is shown that the compressive strain characteristic of the Ga_{z}In_{1-z}P strain compensation barrier greatly or negatively affects the non-uniform condition. In addition, a greatly improved characteristic is confirmed even when the Ga_{z}In_{1-z}P strain condition is zero strain, and such a result shows that non-uniformity of the In_{0.15}Ga_{0.85}As/GaAs_{0.991}P_{0.09} MQW layer is improved by the GaAs buffer layer essentially inserted in the boundary surface when the Ga_{z}In_{1-z}P strain compensation barrier is applied.

According to the present invention, a problem according to the strain of the quantum well layer of an infrared light emitting diode of 1,000 nm center wavelength, which uses a GaAs substrate having a high lattice matching rate and an effect of high cost reduction (economical efficiency), is solved, and thus an infrared light emitting diode with improved light emitting efficiency is provided.

In the present invention, as the active layer of the 1,000 nm infrared light emitting diode with compensated strain improves a non-uniform strain condition of the InGaAs quantum well layer having compressive strain and the GaAsP quantum barrier having tensile strain through the GaInP strain compensation barrier and the buffer layers formed on the top and bottom surfaces of the GaInP strain correction layer, a high-efficiency 1,000 nm infrared light emitting diode having efficiency relatively increased by 20% is provided.

According to the present invention, the defect caused by compressive strain of the quantum well layer having large compressive strain with respect to the substrate can be solved.

What is claimed is:

1. An infrared light emitting diode comprising:
an InₓGa₁₋ₓAs quantum well layer (0.13≤x≤0.15) having compressive strain;
a GaAs_{1-y}P_{y} quantum barrier layer (0.07≤y≤0.11) having tensile strain; and
an active layer including a GaInP strain compensation barrier having compressive strain lower than that of the quantum barrier layer, and a GaAs buffer layer.

2. The infrared light emitting diode according to claim 1, wherein the InGaAs quantum well layer and the GaAsP quantum barrier layer are alternately stacked, and the GaInP strain compensation barrier is positioned between the alternately stacked InGaAs quantum well layer and GaAsP quantum barrier layer.

3. The infrared light emitting diode according to claim 1, wherein the GaAs buffer layer is stacked between the InGaAs quantum well layer and GaInP strain compensation barrier and between the GaAsP quantum barrier layer and the GaInP strain correction layer.

4. The infrared light emitting diode according to claim 1, wherein the InGaAs quantum well layer and the GaAsP quantum barrier layer are alternately stacked, and a GaAs buffer layer, a GaInP strain compensation barrier and a GaAs buffer layer are grown and stacked between the InGaAs quantum well layer and the GaAsP quantum barrier layer.

5. The infrared light emitting diode according to claim 1, wherein the infrared light emitting diode is an infrared light emitting diode having a 1,000 nm center wavelength.

6. The infrared light emitting diode according to claim 5, comprising:
a GaAs substrate;
a first type AlGaAs lower confinement layer grown on the substrate;
an active layer grown on the first type AlGaAs lower confinement layer;
a second type AlGaAs upper confinement layer grown on the active layer;
a p-type window layer formed on the upper confinement layer; and
an upper electrode and a lower electrode respectively contacting with a top surface and a bottom surface of the p-type window layer and the GaAs substrate.

7. The infrared light emitting diode according to claim 1, wherein the quantum well layer is In_{0.15}Ga_{0.85}As, and the quantum barrier layer is GaAs_{0.91}P_{0.09}.

8. The infrared light emitting diode according to claim 1, wherein the GaInP strain compensation barrier is zero strain GaInP.

9. The infrared light emitting diode according to claim 1, wherein the GaInP strain compensation barrier is Ga_{z}In_{1-z}P, wherein 0.50<z<0.59.

10. The infrared light emitting diode according to claim 1, wherein GaAs is a un-doped GaAs layer.
